(19) United States
(12) Patent Application Publication
(10) Pub. No.: US 2023/0411311 A1
(43) Pub. Date: Dec. 21, 2023

(54) SEMICONDUCTOR CHIP AND SEMICONDUCTOR DEVICE

(71) Applicant: ROHM Co., LTD., Kyoto (JP)

(72) Inventor: Daisuke UCHIMOTO, Kyoto (JP)

(21) Appl. No.: 18/333,879

(22) Filed: Jun. 13, 2023

(30) Foreign Application Priority Data
Jun. 17, 2022 (JP) 2022-098192

(51) Int. Cl. H01L 23/62; H01L 23/00; H03K 17/082

(52) U.S. Cl. CPC H01L 23/62; H01L 24/48; H03K 17/0822; H01L 2224/48175

(57) ABSTRACT

Disclosed herein is a semiconductor chip including a power transistor, a plurality of pads, a plurality of wirings each configured to provide electrical continuity between each of the plurality of pads and one end of the power transistor, and a current detection circuit configured to detect, as a sense voltage, at least one of voltage drops occurring in the plurality of wirings, respectively, according to a shunt current flowing through each of the plurality of wirings and a wiring resistance component of each of the plurality of wirings.

### CROSS REFERENCE TO RELATED APPLICATIONS

This application claims priority benefit of Japanese Patent Application No. JP 2022-098192 filed in the Japan Patent Office on Jun. 17, 2022. Each of the above-referenced applications is hereby incorporated herein by reference in its entirety.

### BACKGROUND

The present disclosure relates to a semiconductor chip and a semiconductor device.

A current detection method using a resistance component of a wire bonded to a power transistor as a sense resistor for current detection has been proposed (see Japanese Patent Laid-open No. 2006-109665, Japanese Patent Laid-open No. 2008-236528, and Japanese Patent Laid-open No. 2004-080087, for example).

### BRIEF DESCRIPTION OF THE DRAWINGS

FIG. 1 is a diagram illustrating a comparative example of a semiconductor device;

FIG. 2 is a diagram illustrating a semiconductor device according to a first embodiment of the present disclosure;

FIG. 3 is a diagram illustrating a circuit layout of the first embodiment;

FIG. 4 is a diagram illustrating a semiconductor device according to a second embodiment of the present disclosure;

FIG. 5 is a diagram illustrating a circuit layout (in which metal wirings are not depicted) of the second embodiment; and

FIG. 6 is a diagram illustrating a circuit layout (in which metal wirings are depicted) of the second embodiment.

### DETAILED DESCRIPTION

### Semiconductor Device (Comparative Example)

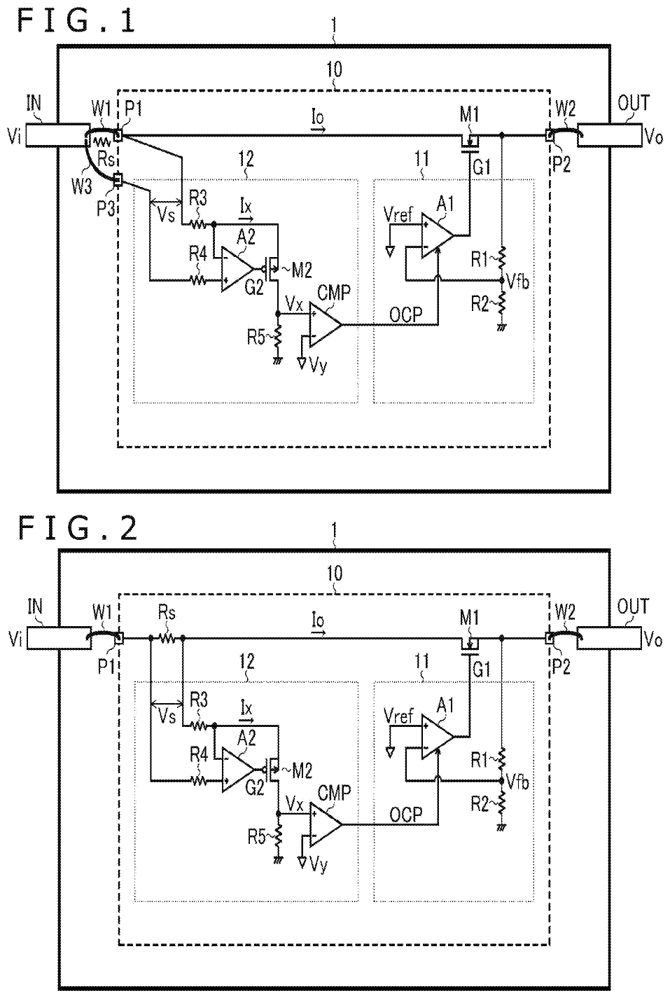

FIG. 1 is a diagram illustrating a comparative example of a semiconductor device (=a general configuration example to be compared with first and second embodiments described later). A semiconductor device 1 of this comparative example is a linear power supply integrated circuit (IC) that steps down an input voltage Vi to generate an output voltage Vo. Referring to this figure, the semiconductor device 1 is formed by sealing a semiconductor chip 10, an input electrode IN, an output electrode OUT, and wires W1 to W3 in a package.

Various circuit elements are integrated in the semiconductor chip 10 in order to implement a power supply function (details will be described later). Further, the semiconductor chip 10 also includes pads P1 to P3 for obtaining electrical continuity with the input electrode IN and the output electrode OUT, respectively.

The input electrode IN is an external electrode to which the input voltage Vi is applied. Incidentally, one end of the input electrode IN is exposed from the package of the semiconductor device 1.

The output electrode OUT is an external electrode to which the output voltage Vo is applied. Incidentally, one end of the output electrode OUT is exposed from the package of the semiconductor device 1.

The wire W1 is laid so as to establish bonding between the other end of the input electrode IN and the pad P1 of the semiconductor chip 10.

The wire W2 is laid so as to establish bonding between the other end of the output electrode OUT and the pad P2 of the semiconductor chip 10.

The wire W3 is laid so as to establish bonding between the other end of the input electrode IN and the pad P3 of the semiconductor chip 10.

### (Semiconductor Chip)

Next, the internal configuration of the semiconductor chip 10 will be described with reference to FIG. 1. The semiconductor chip 10 includes a power transistor M1 (N-channel type metal oxide semiconductor field effect transistor (NMOSFET) in this figure), a driver 11, and a current detection circuit 12.

The power transistor M1 is connected at a position between the pads P1 and P2. Referring to this figure, a drain of the power transistor M1 is connected to the pad P1. A source of the power transistor M1 is connected to the pad P2. A gate of the power transistor M1 is connected to an application terminal of a gate signal G1 (=an output terminal of the driver 11).

The on-resistance of the power transistor M1 changes according to the gate signal G1. When the power transistor M1 is an NMOSFET, the on-resistance of the power transistor M1 decreases as the gate signal G1 increases, and increases as the gate signal G1 decreases. Therefore, an output current Io flowing through the power transistor M1 increases as the gate signal G1 increases, and decreases as the gate signal G1 decreases.

The driver 11 drives and controls the power transistor M1 such that the output voltage Vo output from the source of the power transistor M1 (more precisely, a feedback voltage Vfb corresponding to the output voltage Vo) agrees with a reference voltage Vref. Referring to this figure, the driver 11 includes resistors R1 and R2 and an operational amplifier A1.

The resistors R1 and R2 are connected in series between the source of the power transistor M1 (=a terminal to which the output voltage Vo is applied) and a ground terminal. Therefore, the feedback voltage Vfb (=Vo×R2/(R1+R2)) obtained by dividing the output voltage Vo appears at a connection node between the resistors R1 and R2. Note that, when the output voltage Vo is within the input dynamic range of the operational amplifier A1, the resistors R1 and R2 may be omitted and the output voltage Vo may be directly input to the operational amplifier A1.

The operational amplifier A1 controls the gate signal G1 of the power transistor M1 such that the reference voltage Vref input to a non-inverting input terminal (+) thereof and the feedback voltage Vfb input to an inverting input terminal (−) thereof agree with each other. The gate signal G1 rises when the feedback voltage Vfb is lower than the reference voltage Vref, and falls when the feedback voltage Vfb is higher than the reference voltage Vref.

Further, the operational amplifier A1 also has a function of forcibly lowering the gate signal G1 to a low level according to an overcurrent protection signal OCP.

The current detection circuit 12 is an overcurrent protection circuit that detects a sense voltage Vs generated between the pads P1 and P3 and generates the overcurrent protection signal OCP so as to limit the output current Io flowing through the power transistor M1. Referring to this drawing, the current detection circuit 12 includes a transistor M2 (P-channel type MOSFET (PMOSFET) in this figure), an operational amplifier A2, a comparator CMP, and resistors R3 to R5.

A first end of the resistor R3 is connected to the pad P1. A second end of the resistor R3 is connected to the source of the transistor M2 and the inverting input terminal (−) of the operational amplifier A2. A first end of the resistor R4 is connected to the pad P3. A second end of the resistor R4 is connected to the non-inverting input terminal (+) of the operational amplifier A2. The output terminal of the operational amplifier A2 is connected to a gate of the transistor M2. A connection node between a drain of the transistor M2 and a first end of the resistor R5 (=corresponding to an application terminal of a node voltage Vx) is connected to a non-inverting input terminal (+) of the comparator CMP. A second end of the resistor R5 is connected to the ground terminal. An inverting input terminal (−) of the comparator CMP is connected to an application terminal of a threshold voltage Vy. An output terminal of the comparator CMP (=corresponding to an application terminal of the overcurrent protection signal OCP) is connected to a control terminal of the operational amplifier A1.

The operational amplifier A2 controls a gate signal G2 of the transistor M2 such that the non-inverting input terminal (+) thereof and the inverting input terminal (−) thereof are imaginarily short-circuited. At this time, a current Ix (=Vs/R3) corresponding to the sense voltage Vs flows through the current path from the pad P1 through the resistor R3, the transistor M2, and the resistor R5 to the ground terminal. As a result, the node voltage Vx (=Vs×R5/R3) corresponding to the sense voltage Vs appears at a connection node between the drain of the transistor M2 and the first end of the resistor R5.

Note that the sense voltage Vs increases as the output current Io increases, and decreases as the output current Io decreases. Therefore, the node voltage Vx also increases as the output current Io increases, and decreases as the output current Io decreases.

The comparator CMP generates the overcurrent protection signal OCP by comparing the node voltage Vx input to the non-inverting input terminal (+) and the threshold voltage Vy input to the inverting input terminal (−). The overcurrent protection signal OCP becomes high level (=logic level when overcurrent is detected) when the node voltage Vx is higher than the threshold voltage Vy, and becomes low level (=logic level when no overcurrent is detected) when the node voltage Vx is lower than the threshold voltage Vy.

In the semiconductor device 1 of this comparative example, a resistance component of the wire W1 is used as a sense resistor Rs for generating the sense voltage Vs corresponding to the output current Io. Therefore, it is not necessary to integrate the sense resistor Rs in the semiconductor chip 10. Also, the layout of the power transistor M1 is facilitated. However, the wire W3 and the pad P3 dedicated to current detection are required only to detect the voltage across the wire W1.

### Semiconductor Device (First Embodiment)

FIG. 2 is a diagram illustrating the semiconductor device according to the first embodiment of the present disclosure. The semiconductor device 1 of the present embodiment is based on the above comparative example (FIG. 1), and the sense resistor Rs is integrated in the semiconductor chip 10. A first end of the sense resistor Rs is connected to the pad P1. A second end of the sense resistor Rs is connected to the drain of the power transistor M1.

As the sense resistor Rs, the resistance component of the metal wiring laid between the pad P1 and the drain of the power transistor M1 may be used, for example.

Further, in association with the above change, the connections of the resistors R3 and R4 are also slightly changed from the above comparative example (FIG. 1). Referring to this figure, the first end of the resistor R3 is connected to the second end of the sense resistor Rs instead of the pad P1. Also, the first end of the resistor R4 is connected to the pad P1 instead of the pad P3.

In the case of the semiconductor device 1 of the present embodiment, the pad P3 and the wire W3 in the comparative example (FIG. 1) are unnecessary.

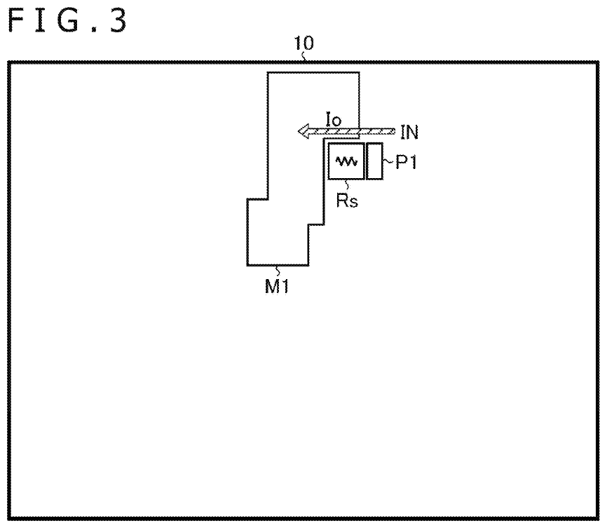

FIG. 3 is a diagram illustrating the circuit layout of the semiconductor chip 10 in the first embodiment. A hatched arrow in the figure indicates the output current Io directed from the pad P1 to the power transistor M1. When the resistance component of the metal wiring laid between the pad P1 and the drain of the power transistor M1 is used as the sense resistor Rs, the metal wiring that functions as the sense resistor Rs is formed outside an element formation region of the power transistor M1 as illustrated in this figure. Therefore, the area efficiency of the semiconductor chip 10 is poor. Also, the layout of the power transistor M1 is difficult. Referring to this figure, the symmetry of the power transistor M1 in a plan view of the semiconductor chip 10 is broken, and there is a possibility that on-resistance may not be lowered sufficiently.

### Semiconductor Device (Second Embodiment)

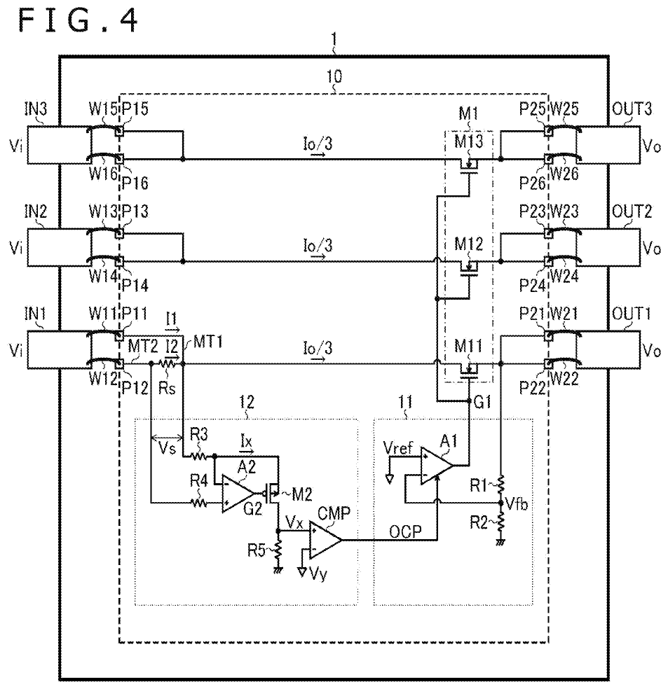

FIG. 4 is a diagram illustrating a semiconductor device according to a second embodiment of the present disclosure. In the semiconductor device 1 of the present embodiment, while being based on the first embodiment mentioned above (FIG. 2), the current path through which the output current Io flows is branched into a plurality of systems, one of which serves as the sense resistor Rs.

Referring to this figure, the power transistor M1 described above is divided into three power transistors M11 to M13 (=corresponding to unit transistors) whose gates are connected in common to each other.

It should be noted that the power transistors M11 to M13 have the same element size (and thus the current capacity). Therefore, a unit output current Io/3, which is obtained by dividing the output current Io flowing through the entire power transistor M1 by three, flows through the power transistors M11 to M13.

Further, the input electrode IN, the output electrode OUT, and the pads P1 and P2 described above are replaced with input electrodes IN1 to IN3, output electrodes OUT1 to OUT3, and pads P11 to P16 and P21 to P26, respectively.

A drain of the power transistor M11 is connected to the pads P11 and P12. A source of the power transistor M11 is connected to the pads P21 and P22. A gate of the power transistor M11 is connected to the application terminal of the gate signal G1 (=the output terminal of the driver 11).

A drain of the power transistor M12 is connected to the pads P13 and P14. A source of the power transistor M12 is connected to the pads P23 and P24. A gate of the power transistor M12 is connected to the application terminal of the gate signal G1 (=the output terminal of the driver 11).

A drain of the power transistor M13 is connected to the pads P15 and P16. A source of the power transistor M13 is connected to the pads P25 and P26. A gate of the power transistor M13 is connected to the application terminal of the gate signal G1 (=the output terminal of the driver 11).

All of the input electrodes IN1 to IN3 are external electrodes to which the input voltage Vi is applied. Incidentally, one end of each of the input electrodes IN1 to IN3 is exposed from the package of the semiconductor device 1.

All of the output electrodes OUT1 to OUT3 are external electrodes to which the output voltage Vo is applied. One end of each of the output electrodes OUT1 to OUT3 is exposed from the package of the semiconductor device 1.

A wire W11 is laid so as to provide bonding between the other end of the input electrode IN1 and the pad P11 of the semiconductor chip 10. A wire W12 is laid so as to provide bonding between the other end of the input electrode IN1 and the pad P12 of the semiconductor chip 10. A wire W13 is laid so as to provide bonding between the other end of the input electrode IN2 and the pad P13 of the semiconductor chip 10. A wire W14 is laid so as to provide bonding between the other end of the input electrode IN2 and the pad P14 of the semiconductor chip 10. A wire W15 is laid so as to provide bonding between the other end of the input electrode IN3 and the pad P15 of the semiconductor chip 10. A wire W16 is laid so as to provide bonding between the other end of the input electrode IN3 and the pad P16 of the semiconductor chip 10.

A wire W21 is laid so as to provide bonding between the other end of the output electrode OUT1 and the pad P21 of the semiconductor chip 10. A wire W22 is laid so as to provide bonding between the other end of the output electrode OUT1 and the pad P22 of the semiconductor chip 10. A wire W23 is laid so as to provide bonding between the other end of the output electrode OUT2 and the pad P23 of the semiconductor chip 10. A wire W24 is laid so as to provide bonding between the other end of the output electrode OUT2 and the pad P24 of the semiconductor chip 10. A wire W25 is laid so as to provide bonding between the other end of the output electrode OUT3 and the pad P25 of the semiconductor chip 10. A wire W26 is laid so as to provide bonding between the other end of the output electrode OUT3 and the pad P26 of the semiconductor chip 10.

Note that any of the pads P11 to P16 and the wires W11 to W16 constitute a current path through which the output current Io (more precisely, shunt currents obtained by branching the output current Io) flows, and are not dedicated to current detection. The same applies to pads P21 to P26 and wires W21 to W26.

The current detection circuit 12 is provided on the input side of the power transistor M11. Referring to this figure, a metal wiring MT1 is laid between the drain of the power transistor M11 and the pad P11 for electrically connecting the two. Further, a metal wiring MT2 is laid between the drain of the power transistor M11 and the pad P12 for electrically connecting the two. Note that shunt currents I1 and I2 (=I1=I2=Io/6) flow through the metal wirings MT1 and MT2, respectively.

Therefore, the current detection circuit 12 detects the voltage drop occurring in the metal wiring MT2 according to the shunt current I2 flowing through the metal wiring MT2 and the wiring resistance component (=sense resistor Rs) of the metal wiring MT2 as the sense voltage Vs (=I2×Rs).

That is, in the semiconductor device 1 of the present embodiment, instead of using the entire metal wiring connected to the drain of the power transistor M1 as the sense resistor Rs, one of the metal wirings made by branching into a plurality of systems (the metal wiring MT2 in this figure) is used as the sense resistor Rs.

Therefore, the pad P3 and the wire W3 in the comparative example (FIG. 1) are unnecessary.

Further, unlike the first embodiment (FIGS. 2 and 3), it becomes easier to form the metal wiring MT2 functioning as the sense resistor Rs on the element forming region of the power transistor M1. Therefore, the area efficiency of the semiconductor chip 10 can be improved. Moreover, it is not necessary to disarrange the layout of the power transistor M1.

The current detection circuit 12 may be provided on the output side of the power transistor M11.

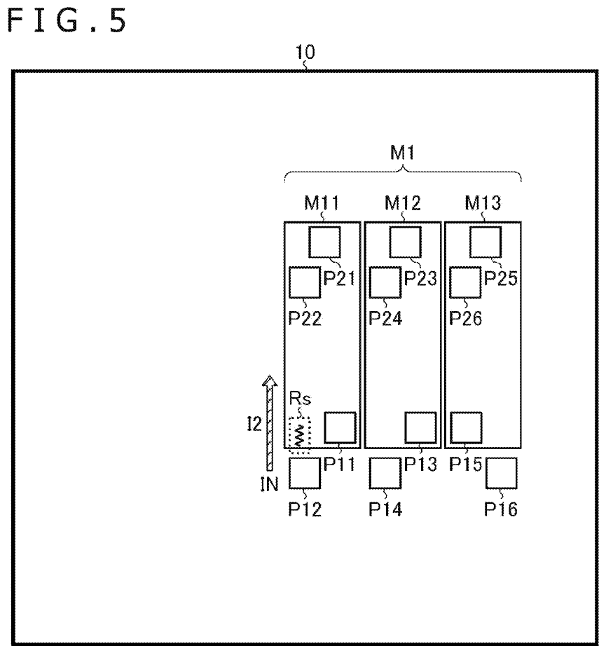

FIG. 5 is a diagram illustrating a circuit layout (without depiction of metal wiring) of the semiconductor chip 10 in the second embodiment. Note that a hatched arrow in the figure indicates the shunt current I2 flowing from the pad P12 to the power transistor M11.

The power transistors M11 to M13 are formed in a rectangular shape having the same element size when the semiconductor chip 10 is viewed from above. With reference to this figure, the power transistors M11 to M13 are each formed in a rectangular shape having the right and left sides extending in the vertical direction on this drawing surface as long sides and the upper and lower sides extending in the horizontal direction on this drawing surface as short sides. Also, the power transistors M11 to M13 are arranged in the order of M11→M12→M13 from left to right on the drawing surface.

The pad P11 is arranged on the element formation region (lower right corner in this figure) of the power transistor M11. The pad P12 is arranged outside the element formation region (near the left end of the lower side in this figure) of the power transistor M11. The pad P13 is arranged on the element formation region (lower right corner in this figure) of the power transistor M12. The pad P14 is arranged outside the element formation region (near the left end of the lower side in this figure) of the power transistor M12. The pad P15 is arranged on the element formation region (lower left corner in this figure) of the power transistor M13. The pad P16 is arranged outside the element formation region (near the right end of the lower side in this figure) of the power transistor M13.

On the other hand, the pad P21 is arranged on the element forming region (near the center of the upper side in this figure) of the power transistor M11. The pad P22 is arranged on the element forming region (near the upper end of the left side and closer to the lower side than the pad P21 in the figure) of the power transistor M11. The pad P23 is arranged on the element forming region (near the center of the upper side in this figure) of the power transistor M12. The pad P24 is arranged on the element formation region (near the upper end of the left side and closer to the lower side than the pad P23 in the figure) of the power transistor M12. The pad P25 is arranged on the element formation region (near the center of the upper side in this figure) of the power transistor M13. The pad P26 is arranged on the element forming region (near the upper end of the left side and closer to the lower side than the pad P25 in the figure) of the power transistor M13.

Further, as indicated by the broken line frame in this figure, the metal wiring functioning as the sense resistor Rs is laid on the element formation region (lower left corner in this figure) of the power transistor M11.

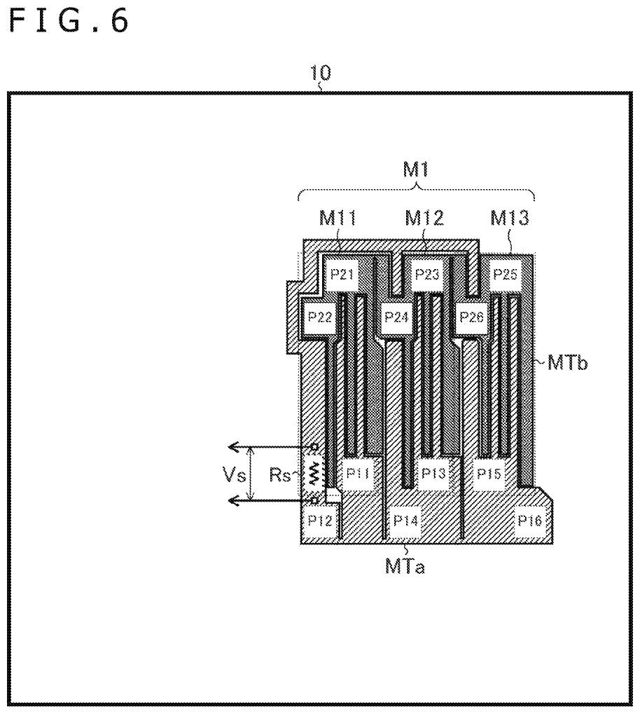

FIG. 6 is a diagram illustrating a circuit layout (in which metal wirings are depicted) of the semiconductor chip 10 in the second embodiment. In this figure, metal wirings MTa and MTb are illustrated so as to be overlaid on the power transistors M11 to M13 in FIG. 5 (depicted by thin broken lines in this figure).

As illustrated in this figure, the plurality of metal wirings MTa and MTb are formed on the element forming region of the power transistor M1 (=power transistors M11 to M13).

In a plan view of the semiconductor chip 10, the metal wiring MTa is formed to have a plurality of comb teeth-shaped projections extending from the outside of the respective lower sides of the power transistors M11 to M13 toward the respective element formation regions of the power transistors M11 to M13 while covering the respective pads P11 to P16. Further, the metal wiring MTa extends from the outside of the left side through and around the upper left corner of the power transistor M11 and extends along the outside of the upper side of each of the power transistors M12 and M13, and then further extends toward the element formation region of each of the power transistors M12 and M13. In this manner, the metal wiring MTa may be formed to provide electrical continuity between the pads P11 to P16 and the drains of the power transistors M11 to M13, respectively. It should be noted that part of the metal wiring MTa can be understood to correspond to the above metal wiring MT2 functioning as the sense resistor Rs.

In a plan view of the semiconductor chip 10, the metal wiring MTb is formed to have a plurality of comb teeth-shaped projections extending downward on the drawing surface from the vicinity of the upper side of each of the power transistors M11 to M13, on the respective element forming regions of the power transistors M11 to M13 while covering the pads P21 to P26. In this manner, the metal wiring MTb may be formed to provide electrical continuity between the pads P21 to P26 and the sources of the power transistors M11 to M13, respectively. Note that the comb teeth-shaped projections of the metal wiring MTa and the comb teeth-shaped projections of the metal wiring MTb are laid out so as to mesh with each other. Therefore, it becomes difficult for the current to concentrate on parts of the drain and source.

As illustrated in this figure, part of the metal wiring MTa functioning as the sense resistor Rs is laid on the element formation region (lower left corner in the figure) of the power transistor M11. Therefore, the area efficiency of the semiconductor chip 10 can be improved as compared with the configuration in which the sense resistor Rs is provided outside the element forming region of the power transistor M1.

A part of the metal wiring MTa from which the sense voltage Vs is drawn out is laid so as to have a higher wiring resistance component (for example, a narrower wiring width) than the remaining part of the metal wiring MTa. Therefore, even if the shunt current I2 flowing through the metal wiring MT2 (see FIG. 4) described above is smaller than the output current Io flowing through the entire power transistor M1, detection of the sense voltage Vs is unlikely to be hindered.

Further, regarding the metal wiring MTa, even if the wiring resistance component of the part corresponding to the metal wiring MT2 is larger than the wiring resistance components of the other parts, the combined resistance value of the entire metal wiring MTa is not significantly affected.

The part corresponding to the metal wiring MT2 is laid on the outer edge of the power transistor M1. Therefore, it is not necessary to rearrange the layout of the power transistor M1 in order to extract the sense voltage Vs. As a result, the on-resistance of the power transistor M1 is less likely to be adversely affected.

### (Overview)

In the following, the various embodiments described above will be comprehensively described.

For example, the semiconductor chip disclosed in the present specification has a configuration (first configuration) having a power transistor, a plurality of pads, and a plurality of wirings each configured to provide electrical continuity between each of the plurality of pads and one end of the power transistor, and a current detection circuit configured to detect, as a sense voltage, at least one of voltage drops occurring in the plurality of wirings, respectively, according to the shunt current flowing through each of the plurality of wirings and the wiring resistance component of each of the plurality of wirings.

It is to be noted that, in the semiconductor chip according to the first configuration, a configuration (second configuration) may also be used, in which the wiring from which the sense voltage is extracted among the plurality of wirings is laid on the element forming region of the power transistor.

In the semiconductor chip according to the first or second configuration, a configuration (third configuration) may also be used, in which the wiring from which the sense voltage is extracted among the plurality of wirings has a higher wiring resistance component than the remaining wirings.

Further, in the semiconductor chip according to any one of the first to third configurations, a configuration (fourth configuration) may also be used, in which the power transistor is divided into a plurality of unit transistors whose control terminals are connected in common to each other.

In the semiconductor chip according to the fourth configuration, a configuration (fifth configuration) may also be used, in which the plurality of unit transistors have the same current capability.

In the semiconductor chip according to any one of the first to fifth configurations, a configuration (sixth configuration) may also be used, in which the current detection circuit is provided on at least one of the input side and the output side of the power transistor.

In the semiconductor chip according to any one of the first to sixth configurations, a configuration (seventh configuration) may also be used, in which the current detection circuit is an overcurrent protection circuit configured to detect the sense voltage and limit the output current flowing through the power transistor.

In the semiconductor chip according to the seventh configuration, a configuration (eighth configuration) may also be used, in which the current detection circuit includes a comparator configured to compare the sense voltage or a voltage corresponding thereto with a predetermined threshold voltage to generate an overcurrent protection signal.

Further, the semiconductor chip according to any one of the first to eighth configurations may have a configuration (ninth configuration) that further includes a driver configured to drive and control the power transistor such that the output voltage output from the power transistor or the feedback voltage corresponding to the output voltage agrees with a reference voltage.

Further, for example, the semiconductor device disclosed in the present specification has a configuration (tenth configuration) including a semiconductor chip having any one of the first to ninth configurations, a plurality of external electrodes, and wires configured to establish bonding between the plurality of external electrodes and the plurality of pads.

### (Other Modifications)

It should be noted that the various technical features disclosed in the present specification can be modified in various ways in addition to the above embodiments without departing from the gist of the technical creation.

In addition, the various technical features disclosed in the present specification can be applied to power supplies in general (in particular, a primary power supply for an in-vehicle battery, etc.) including direct current to direct current (DC/DC) converters, etc. without limiting to the linear power supply IC (low drop out (LDO) regulator, etc.) described above. Further, the various technical features disclosed in the present specification can be applied to all circuits using power transistors (switch circuits, inverter circuits, and other circuits).

That is, the above-described embodiments should be considered as examples and not restrictive in all respects. Moreover, the technical scope of the present disclosure should be understood to be defined by the scope of claims and include all modifications within the meaning and scope equivalent to the scope of the claims.

According to the present disclosure, a semiconductor chip and a semiconductor device capable of detecting an output current flowing through a power transistor can be provided without requiring wires and pads dedicated for current detection.

What is claimed is:

1. A semiconductor chip comprising:
a power transistor;
a plurality of pads;
a plurality of wirings each configured to provide electrical continuity between each of the plurality of pads and one end of the power transistor; and
a current detection circuit configured to detect, as a sense voltage, at least one of voltage drops occurring in the plurality of wirings, respectively, according to a shunt current flowing through each of the plurality of wirings and a wiring resistance component of each of the plurality of wirings.

2. The semiconductor chip according to claim 1, wherein
a wiring which is among the plurality of wirings and from which the sense voltage is extracted is laid on an element forming region of the power transistor.

3. The semiconductor chip according to claim 1, wherein
a wiring which is among the plurality of wirings and from which the sense voltage is extracted has the wiring resistance component larger than those of remaining wirings.

4. The semiconductor chip according to claim 1, wherein
the power transistor is divided into a plurality of unit transistors whose control terminals are each connected in common to each other.

5. The semiconductor chip according to claim 4, wherein
the plurality of unit transistors have a same current capability.

6. The semiconductor chip according to claim 1, wherein
the current detection circuit is provided on at least one of an input side and an output side of the power transistor.

7. The semiconductor chip according to claim 1, wherein
the current detection circuit is an overcurrent protection circuit configured to detect the sense voltage and limit an output current flowing through the power transistor.

8. The semiconductor chip according to claim 7, wherein
the current detection circuit includes a comparator configured to compare the sense voltage or a voltage corresponding to the sense voltage with a predetermined threshold voltage to generate an overcurrent protection signal.

9. The semiconductor chip according to claim 1, further comprising:
a driver configured to drive and control the power transistor such that an output voltage output from the power transistor or a feedback voltage corresponding to the output voltage agrees with a reference voltage.

10. A semiconductor device comprising:
the semiconductor chip according to claim 1;
a plurality of external electrodes; and
a wire configured to provide bonding between the plurality of external electrodes and the plurality of pads.
